(19) United States
(12) Patent Application Publication
(10) Pub. No.: US 2012/0081118 A1
(43) Pub. Date: Apr. 5, 2012

(54) SKEWED RADIO FREQUENCY COIL ARRAYS FOR MAGNETIC RESONANCE IMAGING

(76) Inventors: Ek T. Tan, Halfmoon, NY (US); Stephen J. Riederer, Rochester, MN (US)

(21) Appl. No.: 13/246,750

(22) Filed: Sep. 27, 2011

Related U.S. Application Data
(60) Provisional application No. 61/386,990, filed on Sep. 27, 2010.

(51) Int. Cl. G01R 33/3415

(52) U.S. Cl. 324/318

(57) ABSTRACT

A radio frequency (RF) coil array configured for use with a magnetic resonance imaging (MRI) system and that includes coil elements with a skewed coil geometry is provided. The coil elements are skewed with respect to a given direction, such as the slice-encoding direction of an MRI system, such that a variation in spatial sensitivity along that direction is provided. This spatial sensitivity variation allows for parallel imaging acceleration along the direction of the variation, which provides improved performance over standard rectangular geometries in performing acceleration along the slice-encode direction for three-dimensional axial acquisitions.

### CROSS-REFERENCE

This application is based on, claims priority to, and incorporates herein by reference U.S. Provisional Application Ser. No. 61/386,990, filed Sep. 27, 2010, and entitled “SKEWED RADIO FREQUENCY COIL ARRAYS FOR MAGNETIC RESONANCE IMAGING.”

### STATEMENT REGARDING FEDERALLY SPONSORED RESEARCH

This invention was made with government support under grant number NIH EB000212, awarded by the National Institutes of Health. The government has certain rights in the invention.

### FIELD OF THE INVENTION

The field of the invention is magnetic resonance imaging (“MRI”) systems. More particularly, the invention relates to radio frequency (“RF”) coils for use with parallel MRI techniques.

### BACKGROUND OF THE INVENTION

Magnetic resonance imaging (“MRI”) uses the nuclear magnetic resonance (“NMR”) phenomenon to produce images. When a substance such as human tissue is subjected to a uniform magnetic field (polarizing field B₀), the individual magnetic moments of the nuclei in the tissue attempt to align with this polarizing field, but precess about it in random order at their characteristic Larmor frequency. If the substance, or tissue, is subjected to a magnetic field (excitation field B₁) that is in the x-y plane and that is near the Larmor frequency, the net aligned moment, M_{z}, may be rotated, or “tipped,” into the x-y plane to produce a net transverse magnetic moment M_{xy}. A signal is emitted by the excited nuclei or “spins,” after the excitation signal B₁ is terminated, and this signal may be received and processed to form an image.

When utilizing these “MR” signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received MR signals are digitized and processed to reconstruct the image using one of many well known reconstruction techniques.

Depending on the technique used, many MR scans currently require many minutes to acquire the necessary data used to produce medical images. The reduction of this scan time is an important consideration, since reduced scan time increases patient throughout, improves patient comfort, and improves image quality by reducing motion artifacts. Many different strategies have been developed to shorten the scan time.

One such strategy is referred to generally as “parallel MRI” (“pMRI”). Parallel MRI techniques use spatial information from arrays of radio frequency (“RF”) receiver coils to substitute for the spatial encoding that would otherwise have to be obtained in a sequential fashion using RF pulses and magnetic field gradients, such as phase and frequency encoding gradients. Each of the spatially independent receiver coils of the array carries certain spatial information and has a different spatial sensitivity profile. This information is utilized in order to achieve a complete spatial encoding of the received MR signals, for example, by combining the simultaneously acquired data received from each of the separate coils.

Parallel MRI techniques allow an undersampling of k-space by reducing the number of acquired phase-encoded k-space sampling lines, while keeping the maximal extent covered in k-space fixed. The combination of the separate MR signals produced by the separate receiver coils enables a reduction of the acquisition time required for an image, in comparison to a conventional k-space data acquisition, by a factor related to the number of the receiver coils. Thus the use of multiple receiver coils acts to multiply imaging speed, without increasing gradient switching rates or RF power.

Two categories of such parallel imaging techniques that have been developed and applied to in vivo imaging are so-called “image space methods” and “k-space methods.” An exemplary image space method is known in the art as sensitivity encoding (“SENSE”), while an exemplary k-space method is known in the art as simultaneous acquisition of spatial harmonics (“SMASH”). With SENSE, the undersampled k-space data is first Fourier transformed to produce an aliased image from each coil, and then the aliased image signals are unfolded by a linear transformation of the superimposed pixel values. With SMASH, the omitted k-space lines are synthesized or reconstructed prior to Fourier transformation, by constructing a weighted combination of neighboring k-space lines acquired by the different receiver coils. SMASH requires that the spatial sensitivity of the coils be determined, and one way to do so is by “autocalibration” that entails the use of variable density k-space sampling.

The popularity of phased-array coils in MRI has increased over the years due to the highly localized sensitivities of the coils and because of the applicability of such coils to pMRI for accelerating data acquisition speed. With one-dimensional pMRI, acceleration is achieved by under-sampling in one phase-encoding direction. The general steps in pMRI are to estimate the sensitivity profiles of the coils, and to use these profiles to either resolve aliasing or estimate the unacquired k-space samples. The ability to perform pMRI in the phase-encoding direction relies on uniqueness of the coil sensitivity profiles in that direction. In 3DFT imaging there are two phase-encoding directions, phase and slice, that allow for two-dimensional acceleration. Two-dimensional acceleration can provide reduced noise amplification as compared to one-dimensional acceleration for the same net acceleration. Hence, it may be desirable to perform two-dimensional pMRI when acceleration factors of four (two each in phase and slice) and above are needed in 3DFT acquisitions.

With two-dimensional pMRI, unique coil sensitivities are needed in two directions instead of one. This is achievable in several ways, but is most readily done in a coronal or sagittal 3DFT orientation in which the two directions of acceleration, right-left (R/L) and anterior-posterior (NP), are in the transverse plane. Frequency-encoding is hence in the superior-inferior (S/I) direction, aligned with the main magnetic field, B₀. The phased-array coils can be arranged in a single row circumferentially around the transverse plane, which maximizes B₁ reception while creating unique coil sensitivity profiles in that plane. In 3DFT axial acquisition, however, this arrangement will not provide variation of sensitivity profiles in the S/I direction, which is the slice-encoding or z-direction. To provide this variation in sensitivity profiles, multiple rows of coils or some equivalent are needed in the z-direction. This potentially increases the total number of coils elements, which increases hardware costs and the computational burden of image reconstruction. Attempting z-acceleration with rows of coils works well in general, but experiences high noise amplification when the product of coil length and the acceleration factor approaches or exceeds the slab FOV.

Various proposed coil geometries can provide sensitivity variation in the z-direction, but essentially require two or more rows of coil elements. Notably, the double-spiral architecture generates a continuously-varying sensitivity profile in the z-direction. However, it requires a fixed helical angle of forty-five degrees and double the number of coils compared to a single row of phased-arrays.

It would therefore be desirable to provide a radio frequency coil array for use with parallel magnetic resonance imaging that can be utilized to effect spatial encoding along three orthogonal directions without the need for multiple coil elements along multiple directions.

### SUMMARY OF THE INVENTION

The present invention overcomes the aforementioned drawbacks by providing a radio frequency (“RE”) coil array that includes coil elements with a skewed coil geometry that provides improved performance over standard rectangular geometries in performing acceleration, for example, along the slice-encode direction for three-dimensional axial acquisitions.

In accordance with one aspect of the invention, a radio frequency (RF) coil array configured to be coupled to a magnetic resonance imaging (MRI) system is disclosed that includes an electrical coupling configured to provide electrical communication between an RF system that forms a part of the MRI system and the RF coil array and a plurality of conductive coil elements. Each conductive coil element includes a conductive coil loop forming a quadrilateral extending along a first direction away from the electrical coupling and along a second direction extending non-perpendicular to the first direction to form a skew angle between the first direction and a line extending from the second direction and perpendicular to the second direction. The array also includes a coil substrate coupled to the plurality of conductive coil elements to arrange the plurality of conductive coil elements in the coil array and facilitate arrangement of the plurality of conductive coil elements about a subject for imaging during an MRI imaging process.

In accordance with another aspect of the invention, a radio frequency (RF) coil array configured to be coupled to a magnetic resonance imaging (MRI) system is disclosed that includes an electrical coupling configured to provide electrical communication between an RF system that forms a part of the MRI system and the RF coil array and a plurality of conductive coil elements Each conductive coil element includes a conductive coil loop extending away from the electrical coupling along a first direction to define a length of the conductive coil loop and along a second direction to define a width of the conductive coil loop. The length of each conductive coil loop is greater than the width of each conductive coil loop and each conductive loop is skewed at a skew angle with respect to the first direction.

In accordance with yet another aspect of the invention, a radio frequency (RE) coil array configured to be coupled to a magnetic resonance imaging (MRI) system is disclosed that includes a plurality of conductive coil elements. Each conductive coil element includes an input, an output, and a coil loop extending from the input to the output along a direction parallel to and skewed at a skew angle with respect to a slice-encoding direction of the MRI system. The skew angle provides a variation in a spatial sensitivity of the coil loop along the slice-encoding direction.

The foregoing and other aspects and advantages of the invention will appear from the following description. In the description, reference is made to the accompanying drawings which form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is a block diagram of an exemplary magnetic resonance imaging (“MRI”) system that employs the present invention.

FIG. 2 is a block diagram of an exemplary radio frequency (“RE”) system that forms a part of the MRI system of FIG. 1.

FIG. 3 is a pictorial representation of an exemplary coil element for a skewed coil array;

FIGS. 4A and 4B illustrate a comparison between a standard rectangular coil geometry and an exemplary skewed coil geometry.

FIGS. 5A and 5B depict exemplary configurations of an RF coil array utilizing skewed coil elements.

### DETAILED DESCRIPTION OF THE INVENTION

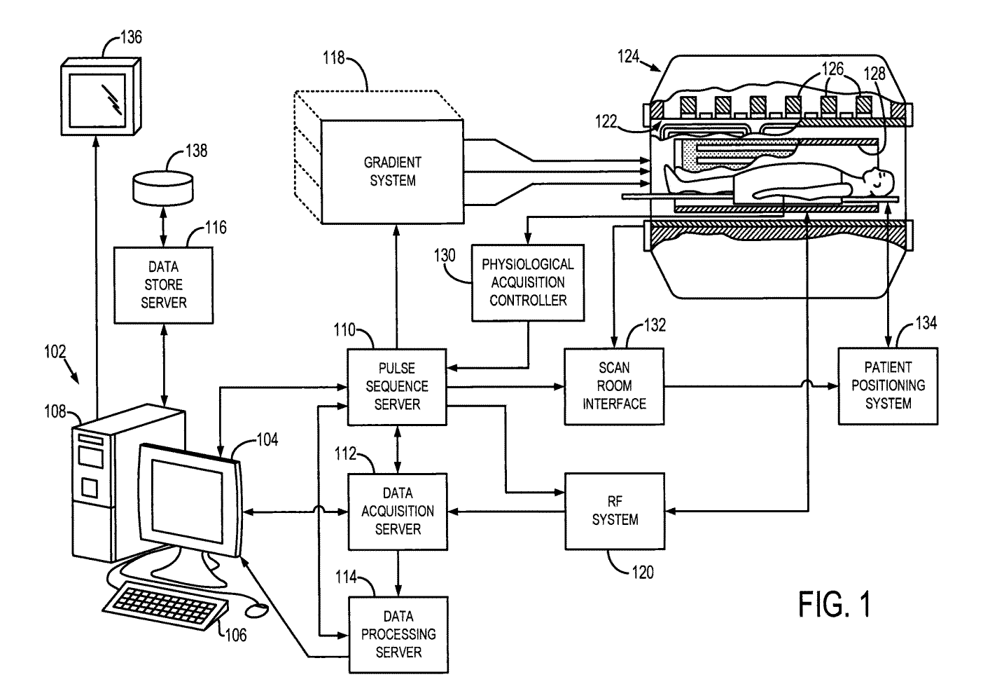

Referring particularly to FIG. 1, an exemplary magnetic resonance imaging (MRI) system 100 is shown. The MRI system 100 includes a workstation 102 having a display 104 and a keyboard 106. The workstation 102 includes a processor 108, such as a commercially available programmable machine running a commercially available operating system. The workstation 102 provides the operator interface that enables scan prescriptions to be entered into the MRI system 100. The workstation 102 is coupled to four servers: a pulse sequence server 110; a data acquisition server 112; a data processing server 114, and a data store server 116. The workstation 102 and each server 110, 112, 114 and 116 are connected to communicate with each other.

The pulse sequence server 110 functions in response to instructions downloaded from the workstation 102 to operate a gradient system 118 and a radiofrequency (RF) system 120. Gradient waveforms necessary to perform the prescribed scan are produced and applied to the gradient system 118, which excites gradient coils in an assembly 122 to produce the magnetic field gradients Gₓ, G_{y}, and G_{z} used for position encoding MR signals. The gradient coil assembly 122 forms part of a magnet assembly 124 that includes a polarizing magnet 126 and a whole-body RF coil 128.

RF excitation waveforms are applied to the RF coil 128, or a separate local coil (not shown in FIG. 1), by the RF system 120 to perform the prescribed magnetic resonance pulse sequence. Responsive MR signals detected by the RF coil 128, or a separate local coil (not shown in FIG. 1), are received by the RF system 120, amplified, demodulated, filtered, and digitized under direction of commands produced by the pulse sequence server 110. The RF system 120 includes an RF transmitter for producing a wide variety of RF pulses used in MR pulse sequences. The RF transmitter is responsive to the scan prescription and direction from the pulse sequence server 110 to produce RF pulses of the desired frequency, phase, and pulse amplitude waveform. The generated RF pulses may be applied to the whole body RF coil 128 or to one or more local coils or coil arrays (not shown in FIG. 1).

The RF system 120 also includes one or more RF receiver channels. Each RF receiver channel includes an RF amplifier that amplifies the MR signal received by the coil 128 to which it is connected, and a detector that detects and digitizes the I and Q quadrature components of the received MR signal. The magnitude of the received MR signal may thus be determined at any sampled point by the square root of the sum of the squares of the I and Q components:

M=\sqrt{I²+Q²} (1)

and the phase of the received MR signal may also be determined:

$$φ = {tan}^{- 1} ( \frac{Q}{I} ) . \qquad ( 2 )$$

The pulse sequence server 110 also optionally receives patient data from a physiological acquisition controller 130. The controller 130 receives signals from a number of different sensors connected to the patient, such as electrocardiograph (ECG) signals from electrodes, or respiratory signals from a bellows or other respiratory monitoring device. Such signals are typically used by the pulse sequence server 110 to synchronize, or “gate,” the performance of the scan with the subject's heart beat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized MR signal samples produced by the RF system 120 are received by the data acquisition server 112. The data acquisition server 112 operates in response to instructions downloaded from the workstation 102 to receive the real-time MR data and provide buffer storage, such that no data is lost by data overrun. In some scans, the data acquisition server 112 does little more than pass the acquired MR data to the data processor server 114. However, in scans that require information derived from acquired MR data to control the further performance of the scan, the data acquisition server 112 is programmed to produce such information and convey it to the pulse sequence server 110. For example, during prescans, MR data is acquired and used to calibrate the pulse sequence performed by the pulse sequence server 110. Also, navigator signals may be acquired during a scan and used to adjust the operating parameters of the RF system 120 or the gradient system 118, or to control the view order in which k-space is sampled. The data acquisition server 112 may also be employed to process MR signals used to detect the arrival of contrast agent in a magnetic resonance angiography (MRA) scan. In all these examples, the data acquisition server 112 acquires MR data and processes it in real-time to produce information that is used to control the scan.

The data processing server 114 receives MR data from the data acquisition server 112 and processes it in accordance with instructions downloaded from the workstation 102. Such processing may include, for example: Fourier transformation of raw k-space MR data to produce two or three-dimensional images; the application of filters to a reconstructed image; the performance of a backprojection image reconstruction of acquired MR data; the generation of functional MR images; and the calculation of motion or flow images.

Images reconstructed by the data processing server 114 are conveyed back to the workstation 102 where they are stored. Real-time images are stored in a data base memory cache (not shown in FIG. 1), from which they may be output to operator display 112 or a display 136 that is located near the magnet assembly 124 for use by attending physicians. Batch mode images or selected real time images are stored in a host database on disc storage 138. When such images have been reconstructed and transferred to storage, the data processing server 114 notifies the data store server 116 on the workstation 102. The workstation 102 may be used by an operator to archive the images, produce films, or send the images via a network to other facilities.

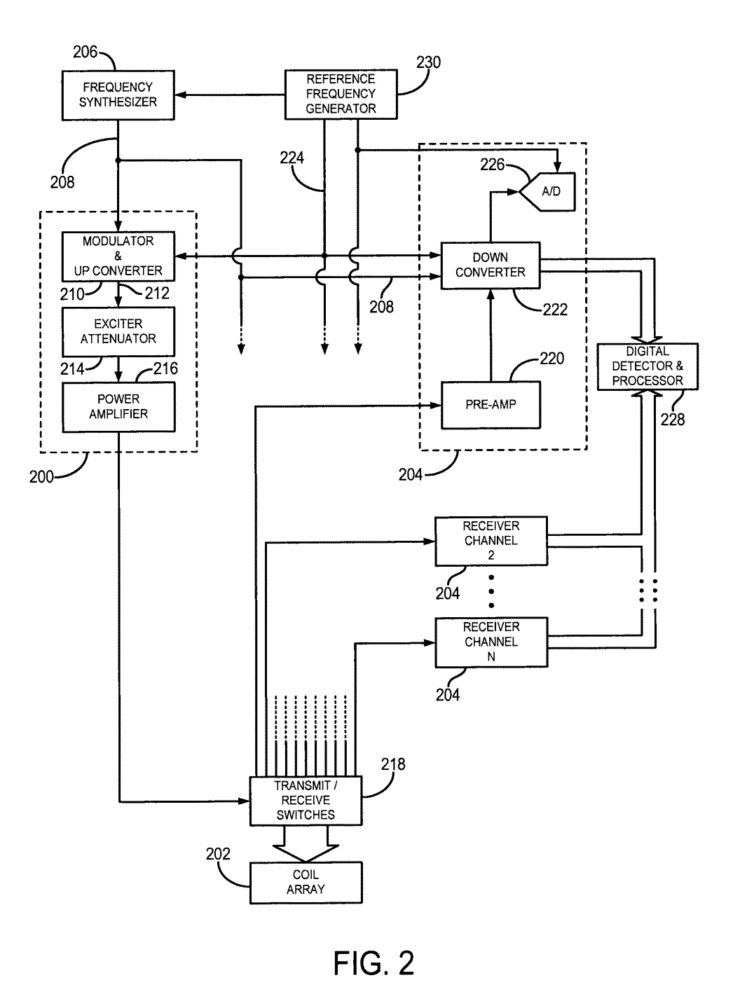

As shown in FIG. 1, the radio frequency (RF) system 120 may be connected to the whole body RF coil 128, or as shown in FIG. 2, a transmitter section of the RF system 120 may connect to at least one transmit channel 200 of a coil array 202, and its receiver section may connect to at least one receiver channel 204 of the coil array 202. Often, the transmitter section is connected to the whole body RF coil 128 or a local transmit coil (not shown), and, in so-called “parallel receiver” coil arrays, each receiver section is connected to a separate receiver channel 204.

Referring particularly to FIG. 2, the RF system 120 includes a transmitter that produces a prescribed RF excitation field. The base, or carrier, frequency of this RF excitation field is produced under control of a frequency synthesizer 206 that receives a set of digital signals from the pulse sequence server 110. These digital signals indicate the frequency and phase of the RF carrier signal produced at an output 208. The RF carrier is applied to a modulator and up converter 210 where its amplitude is modulated in response to a signal, R(t), also received from the pulse sequence server 110. The signal, R(t), defines the envelope of the RF excitation pulse to be produced and is produced by sequentially reading out a series of stored digital values. These stored digital values may be changed to enable any desired RF pulse envelope to be produced.

The magnitude of the RF excitation pulse produced at output 212 is attenuated by an exciter attenuator circuit 214 that receives a digital command from the pulse sequence server 110. The attenuated RF excitation pulses are applied to a power amplifier 216, which drives the RF coil array 202 through a transmit/receive (T/R) switch 218.

Referring still to FIG. 2, the signal produced by the subject is picked up by the coil array 202 and applied to the inputs of a set of receiver channels 204. A pre-amplifier 220 in each receiver channel 204 amplifies the signal by an amount determined by a digital attenuation signal received from the pulse sequence server 110. The received signal is at or around the Larmor frequency, and this high frequency signal is down-converted in a two step process by a down converter 222, which first mixes the detected signal with the carrier signal on line 208 and then mixes the resulting difference signal with a reference signal on line 224. The down converted MR signal is applied to the input of an analog-to-digital (ND) converter 226 that samples and digitizes the analog signal and applies it to a digital detector and signal processor 228 that produces 16-bit in-phase (I) values and 16-bit quadrature (Q) values corresponding to the received signal. The resulting stream of digitized I and Q values of the received signal are output to the data acquisition server 112. The reference signal, as well as the sampling signal applied to the ND converter 226, are produced by a reference frequency generator 230.

In accordance with the present invention, an exemplary coil array 202 includes coil elements that are skewed with respect to a specified direction that is substantially parallel to the length of each coil element. For example, each coil element may be skewed with respect to the longitudinal axis of the MRI system 100, commonly referred to as the z-direction. More generally, each coil element may be skewed such that a length of each coil loop in the array extends at a skew angle from perpendicular to a width of the coil loop. In this configuration, the coil array may be arranged to present coil loops that are skewed with respect to a slice-encoding direction of the MRI system, such that a unique spatial sensitivity of the coil array is provided along the slice-encoding direction, thereby allowing for pMRI acceleration along the slice-encoding direction.

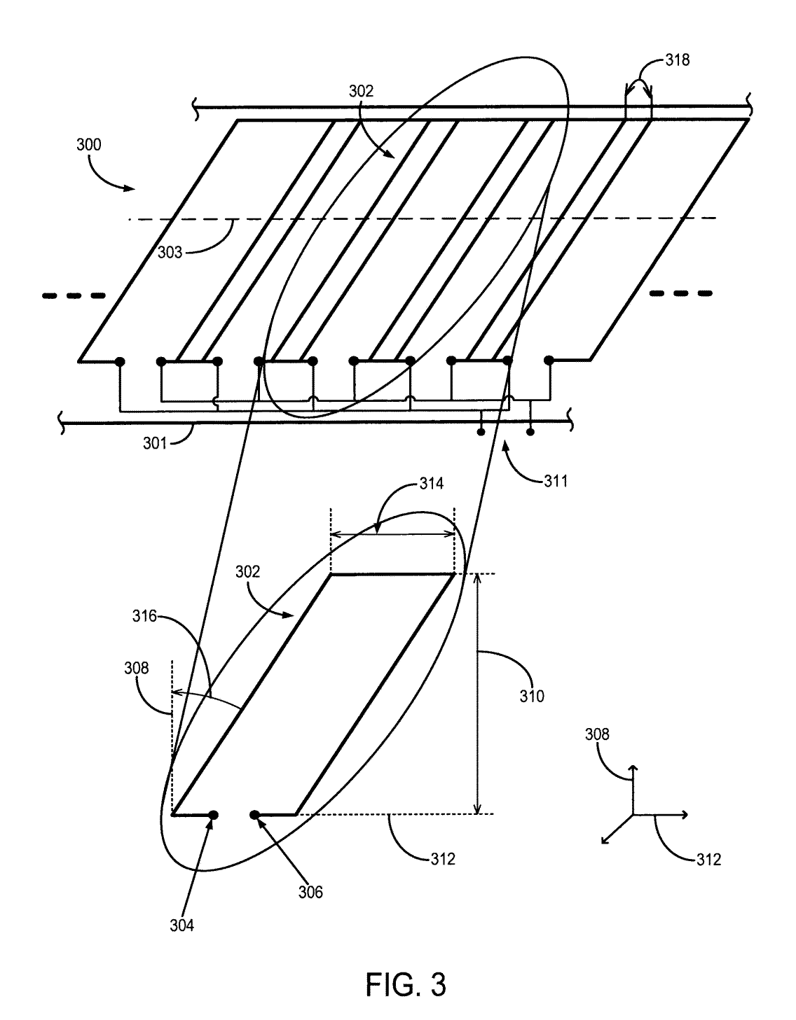

Referring particularly now to FIG. 3, an exemplary skewed coil section 300 is mounted on a substrate 301 that forms a part of an RF coil array configured for use with an MRI system is shown. The coil segment 300 includes a plurality of conductive coil loops 302 that are arranged in a generally linear or substantially linear arrangement such that the conductive coil loops 302 extend in a side-by-side arrangement extending generally along a line 303.

The plurality of conductive coil loops 302 extend away from an input 304 and output 306 along a first direction 308, thereby defining a length 310 of the conductive coil loop 302. The input 304 and output 306 are connected to an electrical coupling 311 configured to couple an coil array formed by the skewed coil section 300 to an MRI system, such as described above. The conductive coil loop 302 also extends along a second direction 312 to define a width 314 of the conductive coil loop 302. As illustrated by the relative positions, the first direction 310 and second direction 312 are perpendicular to one another and may even extend along a respective axis of planes that are perpendicular. The length 310 and the width 314 of the conductive coil loop 302 are dimensioned such that the length 310 is generally greater than the width 314, however, it is contemplated that these dimensions may be equal or inverted. Exemplary dimensions of each coil element 302 are a width 314 of 6.35 centimeters and a length 310 of 25.4 centimeters.

The conductive coil loop 302 is skewed at a skew angle 316 with respect to the first direction 308. As will be described, an RF coil array formed of the coil segment may be advantageously utilized such that the first direction 308 is substantially parallel with the slice-encoding direction or the longitudinal axis of the bore of the MRI system.

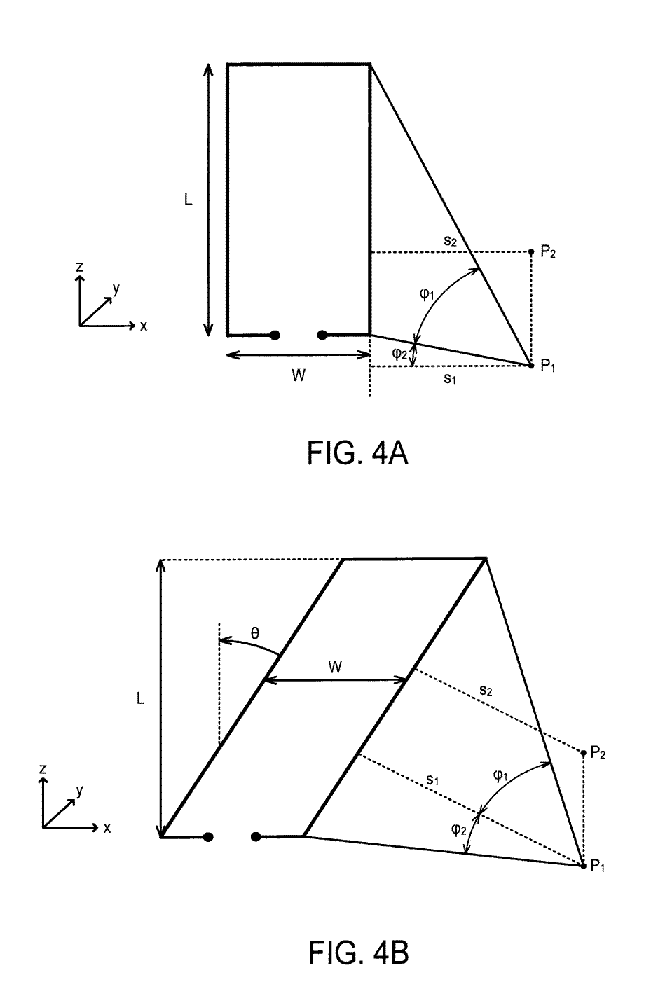

The added variation in spatial sensitivity of a skewed coil element can be illustrated by way of example. Referring now to FIG. 4A, a coil element with a standard rectangular geometry has a width, W, and length, L, whereby the main current-carrying components along the length, L, are positioned so that they are parallel to the z-axis. It can be shown from the Biot-Savart law that the B₁ magnitude at a point, P, from a linear current element is given by:

$$\vert {B}_{1} \vert = \frac{μ I}{4 π s} \cdot \vert sin {φ}_{2} - sin {φ}_{1} \vert ; \qquad ( 3 )$$

where I is the current in the coil element; μ is the magnetic permeability of the coil element; s is a distance perpendicular from the point, P, to the coil element, noting that the distance, s, need not be in the plane of the coil, but may have a displacement from that plane, for example, in the y-direction; B₁ is the magnitude of the magnetic field produced by the current, I, flowing through the coil element, which is inversely related to the distance, s, such that an increase in s results in a sharp fall-off in B₁; and φ₁ and φ₂ are angles to the ends of the coil element.

By way of further example, the rectangular coil element illustrated in FIG. 4A is compared to a coil element having a skewed rectangular geometry, such as the one described above or as shown in FIG. 4B. A coil element with a skewed rectangular geometry has a width, W, and length, L, whereby the main current-carrying components along the length, L, are positioned so that they are parallel to the z-direction. The skewed rectangular coil element is similar to the rectangular element shown in 4A except that it is skewed by a skew angle, θ, with respect to the z-direction, thereby resulting in a coil element shaped as a quadrilateral with two pairs of parallel sides having internal angles that are not right angles.

As illustrated for the rectangular geometry in FIG. 4A, the distance, s₁, from the coil to a point, P₁, is constant when the point is moved in the z-direction to a second point, P₂, so any variation in B₁ along the z-direction is due to the finite length of the coil in terms of the angles φ₁ and φ₂, and is small. However, a rectangle skewed at a skew angle θ, or −θ, relative to the z-direction results in an x-component of the distance, s₁, that changes linearly when the point, P₁, is moved along the z-direction to a new position, P₂, having a new distance, s₂. Hence, there is added variation in the B₁ fall-off along the z-direction with the skewed rectangular geometry.

The B₁ fall-off in the z-direction for the skewed geometry is dependent on the skew angle, θ, and on the width, W, of the coil element. Additionally, the extent of B₁ fall-off is subject to the dimension of the imaging slab, or FOV_{z}, that is defined as both the selective excitation slab and as the endpoints about which z-direction fold-over is done. With reference to FIG. 4B, the change in the x-component of s from the bottom to the top of a slab is FOV_{z}·tan|θ|. Because the change in s is relative to the width of the coil, W, the normalized change in displacement, δ_{z}, is

$${δ}_{Z} = \frac{{FOV}_{Z} \cdot tan \vert θ \vert}{W} ; \qquad ( 4 )$$

whereby δ_{z} can also be a figure of merit for the incremental B₁ fall-off in the z-direction. A skewed coil at a skew angle, B, of zero degrees is identical to a rectangular coil, providing no incremental performance for acceleration in the z-direction, that is, δ_{z}=0. Hence, for a given coil width, W, the B₁ fall-off in the z-direction increases when the absolute value of the skew angle, |θ|, is increased above zero degrees, or when FOV_{z} is increased.

It is noted that with increased skew angles, θ, the expected image signal will decrease. In order to provide a signal decrease no worse than, for example, five percent at the center of the transverse FOV, a skew angle, θ, no larger than, for example, thirty-five (35) degrees can be chosen for the skewed coil prototype. Across the entire FOV, the signal decrease due to a skew angle, θ, of thirty-five degrees is about six percent on average across the simulated profiles. It is contemplated that a comparable signal decrease is apparent for the constructed coil. Greater skew angles can be selected with the noted tradeoff of signal decreases.

Referring again to FIG. 3, when the individual coil elements 302 are arranged to form a segment 300 of an array, the coil elements 302 may be overlapped, as illustrated, by a given distance 318 width-wise in order to suppress mutual inductance. The corners of the elements 302 may also be shaped to overlap perpendicular to each adjacent array to further minimize mutual inductance.

There are several coil design considerations for this skewed coil geometry. First, the coil arrays may be flexible to allow them to conform approximately to the shape of the imaged anatomy. Second, they optionally can be designed to be modular, which allows elements to be removed or added to provide adequate FOV coverage while being as close as possible to the imaged anatomy to maximize SNR. With these considerations, the coil elements can be individually blocked, tuned, and paired for determining the overlap required for minimum mutual inductance. Pairs of coil elements can be connected using plastic snaps at the corners of each element, allowing pairs of elements to be removed or added.

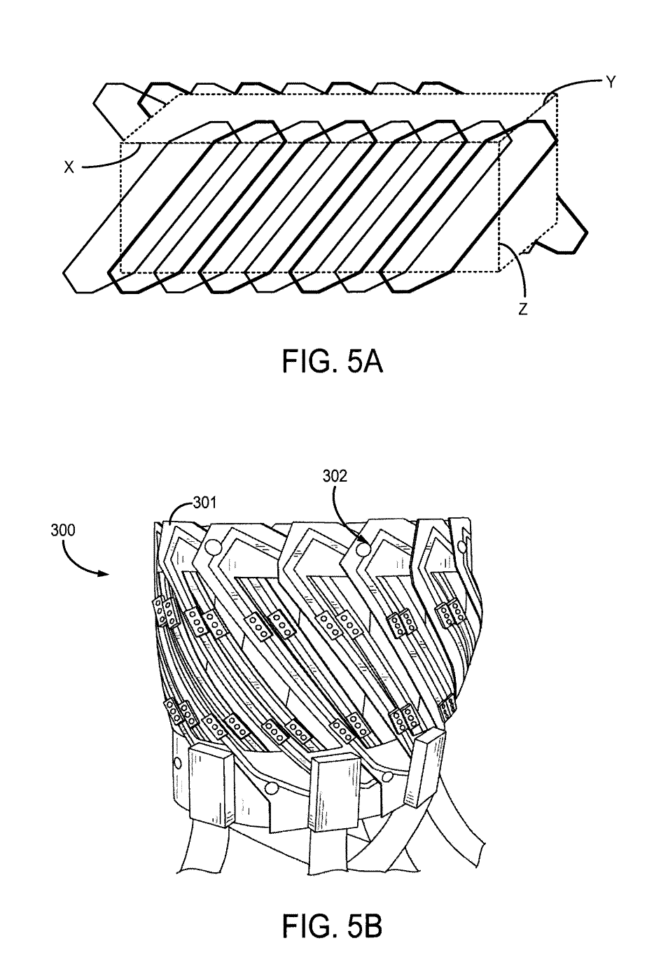

Two exemplary coil array configurations are now described. The first exemplary configuration is a bi-planar configuration for imaging anatomy such as the liver. In such a configuration, the skewed coil elements are arranged as shown in 5A where, for example, the elements are overlapped in the x-direction and placed within two x-z planes, one anterior and one posterior to the patient's torso. The second exemplary configuration is a single row of coil elements connected to form a helix configured to circumscribe a patient's head. FIG. 5B illustrates such a configuration connected at the terminal elements to form a helix. Notably, the coil substrate 301 is illustrated as coupled to the plurality of conductive coil 302 elements to arrange the plurality of conductive coil elements in the coil array 300 and facilitate arrangement of the plurality of conductive coil elements 302 about a subject for imaging during an MRI imaging process.

The design principles for skewed, phased-array coil geometry for axial 3DFT acquisition have been presented. A flexible and modular design facilitates construction of skewed coils for various array layouts. The selection of skew angle of θ=35 degrees for coil construction is based on an expected sensitivity profile and level of noise amplification from parallel acceleration in the slice direction.

The skewed coil element provides a reduced g-factor or noise amplification relative to standard rectangular coil elements. At a net acceleration factor, R, of six (R_{y}=3 and R_{z}=2), two-dimensional images can be acquired that have better overall image quality than images acquired using one-dimensional acceleration schemes (R_{y}=6 and R_{z}=1).

It is contemplated that with two-dimensional acceleration, in vivo aliasing artifacts may be less apparent despite higher g-factors as compared to one-dimensional acceleration. It is contemplated that the aliasing artifacts seen in one-dimensional accelerated images are due to an inadequate number of calibration samples acquired for parallel imaging. Under such an assumption, an added advantage of two-dimensional acceleration may be that two-dimensional acceleration requires fewer calibration samples relative to one-dimensional acceleration. Further optimization with the skewed coil parameters may provide improved g-factors. For example, this optimization can be achieved with larger slab FOVs, or with coils constructed with smaller widths and larger skew angles. Multi-row configurations of skewed elements can also be constructed, and provide improved g-factors relative to multi-row configurations of standard rectangular elements.

The above-described skewed, phased-array coil geometry provides improved performance relative to standard rectangular coil geometries in acceleration along the slice-encoding direction for axial 3DFT acquisition. Improved performance in two-dimensional acceleration with a single row of skewed coil array elements relative to one-dimensional acceleration with a standard coil array is apparent.

The present invention has been described in terms of one or more preferred embodiments, and it should be appreciated that many equivalents, alternatives, variations, and modifications, aside from those expressly stated, are possible and within the scope of the invention.

1. A radio frequency (RF) coil array configured to be coupled to a magnetic resonance imaging (MRI) system, the RF coil array comprising:
an electrical coupling configured to provide electrical communication between an RF system that forms a part of the MRI system and the RF coil array;
a plurality of conductive coil elements, each conductive coil element comprising a conductive coil loop forming a quadrilateral extending along a first direction away from the electrical coupling and along a second direction extending non-perpendicular to the first direction to form a skew angle between the first direction and a line extending from the second direction and perpendicular to the second direction; and
a coil substrate coupled to the plurality of conductive coil elements to arrange the plurality of conductive coil elements in the coil array and facilitate arrangement of the plurality of conductive coil elements about a subject for imaging during an MRI imaging process.

2. The RF coil array of claim 1 wherein the conductive coil loop forms a parallelogram.

3. The RF coil array of claim 1 wherein the plurality of conductive coil elements are arranged in an overlapping orientation within the substantially linear orientation to suppress mutual inductance between each adjacent conductive coil loop in the plurality of conductive coil elements.

4. The RF coil array of claim 1 wherein the skew angle is thirty-five (35) degrees.

5. The RF coil array of claim 1 wherein the RF coil array forms a helix coil array.

6. The RF coil array of claim 1 wherein the RF coil array is configured to be arranged within the MRI system such that the skew angle arranges the first direction to be skewed with respect to a slice-encoding direction of the MRI system, such that a unique spatial sensitivity of the RF coil array is provided along the slice-encoding direction.

7. A radio frequency (RF) coil array configured to be coupled to a magnetic resonance imaging (MRI) system, the RF coil array comprising:
an electrical coupling configured to provide electrical communication between an RF system that forms a part of the MRI system and the RF coil array;
a plurality of conductive coil elements, each conductive coil element comprising:
a conductive coil loop extending away from the electrical coupling along a first direction to define a length of the conductive coil loop and along a second direction to define a width of the conductive coil loop; and
wherein the length of each conductive coil loop is greater than the width of each conductive coil loop and each conductive loop is skewed at a skew angle with respect to the first direction.

8. The RF coil array of claim 7 wherein the conductive coil loop forms one of a quadrilateral and a parallelogram.

9. The RF coil array of claim 7 wherein the plurality of conductive coil elements are arranged in an overlapping orientation within the substantially linear orientation to suppress mutual inductance between each adjacent conductive coil loop in the plurality of conductive coil elements.

10. The RF coil array of claim 7 wherein the second direction extends non-perpendicular to the first direction to form a skew angle between the first direction and a line extending from the second direction and perpendicular to the second direction.

11. The RF coil array of claim 10 wherein the skew angle is thirty-five (35) degrees.

12. The RF coil array of claim 10 wherein the RF coil array is configured to be arranged within the MRI system such that the skew angle arranges the first direction to be skewed with respect to a slice-encoding direction of the MRI system, such that a unique spatial sensitivity of the RF coil array is provided along the slice-encoding direction.

13. The RF coil array of claim 7 wherein the RF coil array forms a helix coil array.

14. A radio frequency (RF) coil array configured to be coupled to a magnetic resonance imaging (MRI) system, the RF coil array comprising:
a plurality of conductive coil elements, each conductive coil element comprising:
an input;
an output;
a coil loop extending from the input to the output along a direction parallel to and skewed at a skew angle with respect to a slice-encoding direction of the MRI system; and
wherein the skew angle provides a variation in a spatial sensitivity of the coil loop along the slice-encoding direction.

15. The RF coil array of claim 14 wherein the skew angle is thirty-five (35) degrees.

16. The RF coil array of claim 14 wherein the conductive coil loop forms one of a quadrilateral and a parallelogram.

17. The RF coil array of claim 14 further comprising a substrate coupled to the plurality of conductive coil elements to arrange the plurality of conductive coil elements in an overlapping arrangement.
